(19) United States
(12) Patent Application Publication
(10) Pub. No.: US 2021/0335980 A1
(43) Pub. Date: Oct. 28, 2021

(54) DISPLAY STRUCTURE AND MANUFACTRUING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jinxue WENG, Wuhan, Hubei (CN)

(21) Appl. No.: 16/615,560

(22) PCT Filed: Mar. 21, 2019
(86) PCT No.: PCT/CN2019/079076

§ 371 Date: Nov. 21, 2019

(30) Foreign Application Priority Data
Nov. 28, 2018 (CN) 201811430589.3

(51) Int. Cl. H01L 27/32; H01L 25/18; H01L 23/00

(52) U.S. Cl. CPC H01L 27/3276; H01L 25/18; H01L 24/13; H01L 24/32; H01L 51/0097; H01L 24/73; H01L 2224/73204; H01L 2224/13025; H01L 2224/32148

(57) ABSTRACT

A display structure and a manufacturing method thereof are provided. The display structure includes a substrate, a display component layer, an insulating protective layer, a plurality of display signal lines, a plurality of first connecting pads and a flip-chip thin-film package, wherein the first connecting pads are disposed on a back surface of the substrate, and connected with the display signal lines; the flip-chip thin-film package has a plurality of second connecting pads electrically connecting to the first connecting pads. The connecting pads disposed on the flip-chip thin-film package are connecting to the connecting pads disposed on the back surface of the display panel, so that achieve no need to bend the display, thereby increasing a screen ratio of the display.

### FIELD OF INVENTION

The present invention relates to a display structure and a manufacturing method thereof, and more particularly to a display structure for improving display screen ratio and a manufacturing method thereof.

### BACKGROUND OF INVENTION

In recent years, as the popularity of smart phones, consumer demand for mobile phone functions has increased, for example, high screen ratio, high resolution, and the like. Therefore, narrow bezel panels have become a trend in the development of mobile phone structures. However, narrow bezel panels still have some limitations in design and manufacturing process. Currently, panels generally increase the screen ratio by bending connection pads of a display to a back surface of the display. However, this kind of structural design that bends the display connection pads is complicated, which has a great influence on module product yield, and limits the possibility of increasing the screen ratio of the display.

Referring to FIG. 1, a schematic view of a bending display structure of prior art is shown. A display structure 1 includes a display area 10, a bendable area 11, a plurality of display signal lines 12, and a thin-film substrate 20. The display area 10 has a flexible substrate extending downward to the bendable area 11. The display signal lines 12 are disposed in the flexible substrate for connecting a plurality of display component of the display area. The flexible substrate may be bent toward a back surface of the display area and connected to the thin-film substrate 20 to control the display components through a controller chip disposed on the thin-film substrate 20.

### Technical Problem

However, after the flexible substrate is bent, there is still a certain bending radius, so that the display structure bezel still needs to retain a certain size to accommodate the flexible substrate, thus limiting the possibility of increasing the screen ratio of the display. Furthermore, the display signal lines are covered with an inorganic layer to obstruct a influence of moisture and oxygen on the display signal lines. However, after the inorganic layer is bent a plurality of times, the inorganic layer may be broken, and moisture and oxygen may permeate along a crack of the inorganic layer, thus causing deterioration or failure of the display.

Therefore, it is necessary to provide a display structure and a manufacturing method thereof to solve the problems of prior art.

### SUMMARY OF INVENTION

In view of above, the present invention provides a display structure and a manufacturing method thereof, so as to solve a problem that a bending area of a display of prior art still has a certain bending radius after the bending area of the display is bent, results that the display cannot increase the screen ratio.

A main object of the present invention is to provide a display structure and a manufacturing method thereof, which can increase the screen ratio of the display.

A secondary object of the present invention is to provide a display structure and a manufacturing method thereof, which can connect connecting pads disposed on a flip-chip thin-film package (chip on film, COF) with connecting pads disposed on a back surface of a display panel, so as to achieve no need to bend display, so that increase the screen ratio of the display.

A secondary object of the present invention is to provide a display structure and a manufacturing method thereof, which can be no need to bend a display to avoid the inorganic layer crack, which may results problem that moisture and oxygen may permeate into the display along the inorganic layer crack to causes deterioration or failure of the display, so as to improve the display reliability and the product life cycles.

In order to achieve the foregoing objects of the present invention, an embodiment of the present invention provides a display structure including: a polyimide thin-film substrate; an organic light emitting diode layer disposed on the polyimide thin-film substrate; an insulating protective layer disposed on the organic light emitting diode layer; a plurality of display signal lines connected to a plurality of display components in the organic light emitting diode layer, and passing through the insulating protective layer, the organic light emitting diode layer, and the polyimide thin-film substrate; a plurality of first connecting pads disposed on a surface of the polyimide thin-film substrate facing away from the organic light emitting diode layer, the plurality of first connecting pads connected to the plurality of display signal lines; and a flip-chip thin-film package disposed on a same side corresponding to the surface of the polyimide thin-film substrate, the flip-chip thin-film package having a plurality of second connecting pads, and the plurality of second connecting pads connected to the plurality of first connecting pads.

In an embodiment of the invention, the plurality of first connecting pads are connected to the plurality of second connecting pads by an anisotropic conductive film.

In an embodiment of the invention, the display structure further including: a back plate disposed between the polyimide thin-film substrate and the flip-chip thin-film package, and at a side of the anisotropic conductive film.

In an embodiment of the invention, the organic light emitting diode layer includes: an insulating layer disposed on the polyimide thin-film substrate; an active layer disposed on the insulating layer; a gate insulating layer disposed on the active layer; a gate disposed on the gate insulating layer; the insulating protective layer disposed on the gate; a first via passing through the insulating protective layer and the gate insulating layer; and a second via passing through the insulating protective layer, the gate insulating layer, the insulating layer, and the polyimide thin-film substrate, wherein the plurality of display signal lines are connected to the active layer through the first via and extending on the insulating protective layer, and are connected to the plurality of first connecting pads through the second via.

In an embodiment of the invention, the polyimide thin-film substrate and the flip-chip thin-film package are disposed in parallel with each other.

Moreover, another embodiment of the present invention provides a display structure including: a substrate; a display component layer disposed on the substrate; an insulating protective layer disposed on the display component layer; a plurality of display signal lines connected to a plurality of display components in the display component layer, and passing through the insulating protective layer, the display component layer and the substrate; a plurality of first connecting pads disposed on a surface of the substrate facing away from the display component layer, the plurality of first connecting pads connected to the plurality of display signal lines; and a flip-chip thin-film package disposed on a same side corresponding to the surface of the substrate, the flip-chip thin-film package having a plurality of second connecting pads, and the plurality of second connecting pads connected to the plurality of first connecting pads.

In an embodiment of the invention, the plurality of first connecting pads are connected to the plurality of second connecting pads by an anisotropic conductive film.

In an embodiment of the invention, the display structure further including: a back plate disposed between the substrate and the flip-chip thin-film package, and at a side of the anisotropic conductive film.

In an embodiment of the invention, the display component layer includes: an insulating layer disposed on the substrate; an active layer disposed on the insulating layer; a gate insulating layer disposed on the active layer; a gate disposed on the gate insulating layer; the insulating protective layer disposed on the gate; a first via passing through the insulating protective layer and the gate insulating layer; and a second via passing through the insulating protective layer, the gate insulating layer, the insulating layer, and the substrate, wherein the plurality of display signal lines are connected to the active layer through the first via and extending on the insulating protective layer, and are connected to the plurality of first connecting pads through the second via.

In an embodiment of the invention, the substrate and the flip-chip thin-film package are disposed in parallel with each other.

Furthermore, another embodiment of the present invention provides a manufacturing method of a display structure, including steps of: providing a display panel, including: a substrate; a display component layer disposed on the substrate; an insulating protective layer disposed on the display component layer; a plurality of display signal lines connected to a plurality of display components in the display component layer, and passing through the insulating protective layer, the display component layer and the substrate; and a plurality of first connecting pads disposed on a surface of the substrate facing away from the display component layer, the plurality of first connecting pads connected to the plurality of display signal lines; providing a flip-chip thin-film package having a plurality of second connecting pads; and electrically connecting the plurality of first connecting pads with the plurality of second connecting pads.

In an embodiment of the invention, the plurality of first connecting pads are connected to the plurality of second connecting pads by an anisotropic conductive film.

In an embodiment of the invention, the flip-chip thin-film package further including a back plate, when the plurality of first connecting pads connecting with the plurality of the second connecting pads, the back plate is in contact with the surface of the substrate.

In an embodiment of the invention, the display component layer includes: an insulating layer disposed on the substrate; an active layer disposed on the insulating layer; a gate insulating layer disposed on the active layer; a gate disposed on the gate insulating layer; the insulating protective layer disposed on the gate; a first via passing through the insulating protective layer and the gate insulating layer; and a second via passing through the insulating protective layer, the gate insulating layer, the insulating layer, and the substrate, wherein the plurality of display signal lines are connected to the active layer through the first via and extending on the insulating protective layer, and are connected to the plurality of first connecting pads through the second via.

In an embodiment of the invention, the substrate and the flip-chip thin-film package are disposed in parallel with each other.

### Beneficial Effect

Compared with the prior art, the display structure and the manufacturing method thereof of the present invention can not only improve the problem that a bending area of a display of prior art still has a certain bending radius after the bending area of the display is bent, results that the display cannot increase the screen ratio. The present invention can also no need to bend the display to avoid the inorganic layer crack, which may results problem that moisture and oxygen may permeate into the display along the inorganic layer crack to causes deterioration or failure of the display, so as to improve the display reliability and the product life cycles.

### DRAWINGS

In order to make the above description of the present invention more comprehensible, the preferred embodiments are described below, and in conjunction with the accompanying drawings, the detailed description is as follows:

FIG. 1 is a schematic view of a bending display structure of prior art.

FIG. 2 is a schematic cross-sectional view of a display structure connecting with a flip-chip package (chip on film, COF) according to an embodiment of the present invention.

FIG. 3 is a cross-sectional view of a display structure according to an embodiment of the present invention.

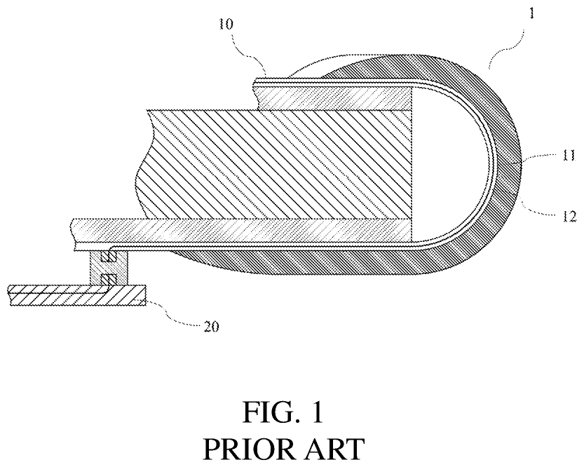

### DETAILED DESCRIPTION OF EMBODIMENTS

The following description of the various embodiments is provided to illustrate the specific embodiments of the invention. Furthermore, the directional terms mentioned in the present invention, such as upper, lower, top, bottom, front, rear, left, right, inner, outer, side, surrounding, central, horizontal, horizontal, vertical, longitudinal, axial, radial, uppermost or lowermost, etc., only refer to the direction of the additional schema. Therefore, the directional terminology used is for the purpose of illustration and understanding of the invention.

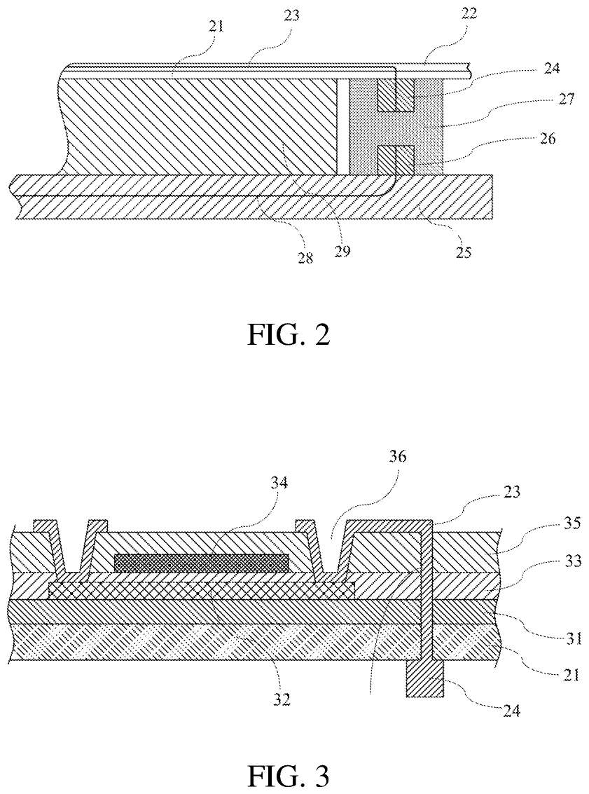

Referring to FIG. 2 and FIG. 3, FIG. 2 is a schematic cross-sectional view of a display structure connecting with a flip-chip package (chip on film, COF) according to an embodiment of the present invention; and FIG. 3 is a cross-sectional view of a display structure according to an embodiment of the present invention. In order to achieve the foregoing objects of the present invention, a display structure and a manufacturing method thereof are provided. The display structure includes a substrate 21, a display component layer 22, an insulating protective layer 35, a plurality of display signal lines 23, a plurality of first connecting pads 24, and a flip-chip thin-film package 25. Optionally, the substrate 21 may be a flexible substrate (for example, a polyimide thin-film). Alternatively, the substrate 21 may be a glass substrate. The display component layer 22 is disposed on the substrate 21. The insulating protective layer 35 is disposed on the display component layer 22. The display signal lines 23 are connected to a plurality of display components in the display component layer 22 and passing through the insulating protective layer 35, the display component layer 22, and the substrate 21. The first connecting pads 24 are disposed on a surface of the substrate 21 facing away from the display component layer 22, and the first connecting pads 24 are connected to the display signal lines 23. Optionally, the display components may be a plurality of thin film transistor components or a plurality of organic light emitting diode components. Optionally, the display component layer 22 further includes an insulating layer 31, an active layer 32, a gate insulating layer 33, a gate 34, a first via 36, and a second via 37. The insulating layer 31 is disposed on the substrate 21. The active layer 32 is disposed on the insulating layer 31. The gate insulating layer 33 is disposed on the active layer 32. The gate 34 is disposed on the gate insulating layer 33. The insulating protective layer 35 is disposed on the gate 34. The first via 36 passes through the insulating protective layer 35 and the gate insulating layer 33. The second via 37 passes through the insulating protective layer 35, the gate insulating layer 33, the insulating layer 31, and the substrate 21, the display signal lines 23 are connected to the active layer 32 through the first via 36 and extending on the insulating protective layer 35, and are connected to the first connecting pads 24 through the second via 37.

Next, referring to FIG. 2, the flip-chip thin-film package 25 is disposed on a same side corresponding to the surface of the substrate 21. Preferably, the substrate 21 and the flip-chip thin-film package 25 are disposed in parallel with each other. In this embodiment, the flip-chip thin-film package 25 has a thin-film substrate, a plurality of traces 28, a plurality of second connecting pads 26, a plurality of flip chip package connecting pads (not shown), and a controller chip (not shown). The traces 28 are disposed on the thin-film substrate. One end of the traces 28 is connected to the second connecting pads 26, and the other end of the traces 28 is connected to the flip chip package connecting pads. The controller chip is disposed on the flip chip package connecting pads by flip chip. The second connecting pads 26 are electrically connected to the first connecting pads 24, such that the controller chip can control the display components through the traces 28 and the display signal lines 23. Optionally, the first connecting pads 24 and the second connecting pads 26 are connected by an anisotropic conductive film 27. In addition, the display structure further has a back plate 29 disposed between the substrate 21 and the flip-chip thin-film package 25 and at a side of the anisotropic conductive film 27. Optionally, when the first connecting pads 24 are electrically connected to the second connecting pads 26, the back plate 29 is in contact with the surface of the substrate 21.

Moreover, another embodiment of the present invention provides a manufacturing method of a display structure, including steps of:

providing a display panel, the display panel including: a substrate 21; a display component layer 22 disposed on the substrate 21; an insulating protective layer 35 disposed on the display component layer 22; a plurality of display signal lines 23 connected to a plurality of display components in the display component layer 22, and passing through the insulating protective layer 35, the display component layer 22 and the substrate 21; and a plurality of first connecting pads 24 disposed on a surface of the substrate 21 facing away from the display component layer 22, the first connecting pads 24 connected to the display signal lines 23;

providing a flip-chip thin-film package 25 having a plurality of second connecting pads 26; and

electrically connecting the first connecting pads 24 with the second connecting pads 26.

Optionally, the first connecting pads 24 are connected to the second connecting pads 26 by an anisotropic conductive film 27. Optionally, the flip-chip thin-film package 25 further including a back plate 29, when the first connecting pads 24 connecting with the second connecting pads 26, the back plate 29 is in contact with the surface of the substrate 21. Optionally, the display component layer 22 includes: an insulating layer 31 disposed on the substrate 21; an active layer 32 disposed on the insulating layer 31; a gate insulating layer 33 disposed on the active layer 32; a gate 34 disposed on the gate insulating layer 33; the insulating protective layer 35 disposed on the gate 34; a first via 36 passing through the insulating protective layer 35 and the gate insulating layer 33; and a second via 37 passing through the insulating protective layer 35, the gate insulating layer 33, the insulating layer 31, and the substrate 21, wherein the display signal lines 23 are connected to the active layer 32 through the first via 36 and extending on the insulating protective layer 35, and are connected to the first connecting pads 24 through the second via 37. Optionally, the substrate 21 and the flip-chip thin-film package 25 are disposed in parallel with each other.

As described above, compared with prior art existing that a bending area of a display still has a certain bending radius after the bending area of the display is bent, results that the display cannot increase the screen ratio. The present invention provides a display structure and a manufacturing method thereof, which can connect connecting pads disposed on a flip-chip thin-film package (chip on film, COF) with connecting pads disposed on a back surface of a display panel, so as to achieve no need to bend display, so that increase the screen ratio of the display. Moreover, the present invention can be no need to bend a display to avoid the inorganic layer crack, which may results problem that moisture and oxygen may permeate into the display along the inorganic layer crack to causes deterioration or failure of the display, so as to improve the display reliability and the product life cycles.

The present invention has been described by the above related embodiments, but the above embodiments are merely examples for implementing the present invention. It must be noted that the disclosed embodiments do not limit the scope of the invention. Rather, modifications and equivalent arrangements are intended to be included within the scope of the invention.

1. A display structure comprising:
a polyimide thin-film substrate;
an organic light emitting diode layer disposed on the polyimide thin-film substrate;
an insulating protective layer disposed on the organic light emitting diode layer;
a plurality of display signal lines connected to a plurality of display components in the organic light emitting diode layer, and passing through the insulating protective layer, the organic light emitting diode layer, and the polyimide thin-film substrate;
a plurality of first connecting pads disposed on a surface of the polyimide thin-film substrate facing away from the organic light emitting diode layer, the plurality of first connecting pads connected to the plurality of display signal lines; and
a flip-chip thin-film package disposed on a same side corresponding to the surface of the polyimide thin-film substrate, the flip-chip thin-film package having a plurality of second connecting pads, and the plurality of second connecting pads connected to the plurality of first connecting pads.

2. The display structure according to claim 1, wherein the plurality of first connecting pads are connected to the plurality of second connecting pads by an anisotropic conductive film.

3. The display structure according to claim 2, the display structure further comprising: a back plate disposed between the polyimide thin-film substrate and the flip-chip thin-film package, and at a side of the anisotropic conductive film.

4. The display structure according to claim 1, wherein the organic light emitting diode layer comprises:
an insulating layer disposed on the polyimide thin-film substrate;
an active layer disposed on the insulating layer;
a gate insulating layer disposed on the active layer;
a gate disposed on the gate insulating layer;
the insulating protective layer disposed on the gate;
a first via passing through the insulating protective layer and the gate insulating layer; and
a second via passing through the insulating protective layer, the gate insulating layer, the insulating layer, and the polyimide thin-film substrate,
wherein the plurality of display signal lines are connected to the active layer through the first via and extending on the insulating protective layer, and are connected to the plurality of first connecting pads through the second via.

5. The display structure according to claim 1, wherein the polyimide thin-film substrate and the flip-chip thin-film package are disposed in parallel with each other.

6. A display structure comprising:
a substrate;
a display component layer disposed on the substrate;
an insulating protective layer disposed on the display component layer;
a plurality of display signal lines connected to a plurality of display components in the display component layer, and passing through the insulating protective layer, the display component layer and the substrate;
a plurality of first connecting pads disposed on a surface of the substrate facing away from the display component layer, the plurality of first connecting pads connected to the plurality of display signal lines; and
a flip-chip thin-film package disposed on a same side corresponding to the surface of the substrate, the flip-chip thin-film package having a plurality of second connecting pads, and the plurality of second connecting pads connected to the plurality of first connecting pads.

7. The display structure according to claim 6, wherein the plurality of first connecting pads are connected to the plurality of second connecting pads by an anisotropic conductive film.

8. The display structure according to claim 7, the display structure further comprising: a back plate disposed between the substrate and the flip-chip thin-film package, and at a side of the anisotropic conductive film.

9. The display structure according to claim 6, wherein the display component layer comprises:
an insulating layer disposed on the substrate;
an active layer disposed on the insulating layer;
a gate insulating layer disposed on the active layer;
a gate disposed on the gate insulating layer;
the insulating protective layer disposed on the gate;
a first via passing through the insulating protective layer and the gate insulating layer; and
a second via passing through the insulating protective layer, the gate insulating layer, the insulating layer, and the substrate,
wherein the plurality of display signal lines are connected to the active layer through the first via and extending on the insulating protective layer, and are connected to the plurality of first connecting pads through the second via.

10. The display structure according to claim 6, wherein the substrate and the flip-chip thin-film package are disposed in parallel with each other.

11. A manufacturing method of a display structure, comprising steps of:
providing a display panel, comprising:
a substrate;
a display component layer disposed on the substrate;
an insulating protective layer disposed on the display component layer;
a plurality of display signal lines connected to a plurality of display components in the display component layer, and passing through the insulating protective layer, the display component layer and the substrate; and
a plurality of first connecting pads disposed on a surface of the substrate facing away from the display component layer, the plurality of first connecting pads connected to the plurality of display signal lines;
providing a flip-chip thin-film package having a plurality of second connecting pads; and
electrically connecting the plurality of first connecting pads with the plurality of second connecting pads.

12. The manufacturing method of the display structure according to claim 11, wherein the plurality of first connecting pads are connected to the plurality of second connecting pads by an anisotropic conductive film.

13. The manufacturing method of the display structure according to claim 12, wherein the flip-chip thin-film package further comprising a back plate, when the plurality of first connecting pads connecting with the plurality of the second connecting pads, the back plate is in contact with the surface of the substrate.

14. The manufacturing method of the display structure according to claim 11, wherein the display component layer comprises:
an insulating layer disposed on the substrate;
an active layer disposed on the insulating layer;
a gate insulating layer disposed on the active layer;
a gate disposed on the gate insulating layer;
the insulating protective layer disposed on the gate;
a first via passing through the insulating protective layer and the gate insulating layer; and
a second via passing through the insulating protective layer, the gate insulating layer, the insulating layer, and the substrate,
wherein the plurality of display signal lines are connected to the active layer through the first via and extending on the insulating protective layer, and are connected to the plurality of first connecting pads through the second via.

15. The manufacturing method of the display structure according to claim 11, wherein the substrate and the flip-chip thin-film package are disposed in parallel with each other.
